(19) United States
(12) Patent Application Publication
(10) Pub. No.: US 2009/0170310 A1
(43) Pub. Date: Jul. 2, 2009

(54) METHOD OF FORMING A METAL LINE OF A SEMICONDUCTOR DEVICE

(75) Inventor: Woo Yung Jung, Seoul (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 12/053,469

(22) Filed: Mar. 21, 2008

(30) Foreign Application Priority Data
Dec. 27, 2007 (KR) 10-2007-138769

(51) Int. Cl. H01L 21/4763

(52) U.S. Cl. 438/645; 257/E21.295

(57) ABSTRACT

In a method of forming a metal line of a semiconductor device, a dielectric film is formed on a semiconductor substrate. A plurality of parallel photoresist patterns are formed over the entire structure including the dielectric film. A spacer is formed on sidewalls of the photoresist patterns. The dielectric film is exposed by removing the photoresist patterns. Damascene patterns are formed by etching the exposed dielectric film. The spacer is removed. Metal material is formed over the entire structure including the damascene patterns and polishing the metal material, thereby forming a metal line.

### CROSS-REFERENCES TO RELATED APPLICATIONS

The present application claims priority to Korean patent application number 10-2007-138769, filed on Dec. 27, 2007, which is incorporated by reference in its entirety.

### BACKGROUND OF THE INVENTION

The present invention relates to a method of forming a metal line of a semiconductor device and, more particularly, to a method of forming a metal line of a semiconductor device, which has a micro metal line pitch.

In general, a method of forming a metal line during semiconductor device fabrication can be classified into a damascene scheme or tungsten (W) etch scheme. In particular, as the integration degree of semiconductor devices increases, the line width decreases.

In order to form a metal line having a micro line width, a micro damascene pattern must be formed. However, a minimum pitch of a pattern, which is formed by a photolithography process during the manufacture of a semiconductor device, is decided by the wavelength of exposure light from an exposure apparatus. In order to form a pattern having a smaller pitch when the integration degree of semiconductor devices increases, light having a wavelength shorter than conventional exposure light must be used. X-ray or e-beam may be used to provide the shorter wavelength, but the use of the X-ray or e-beam is still in an experimental stage to address issues related to technical problems, productivity, etc.

### BRIEF SUMMARY OF THE INVENTION

The present invention is directed towards a method of forming a metal line of a semiconductor device, in which a spacer film is formed on sidewalls of photoresist patterns, micro metal patterns are formed using the spacer as an etch mask, and portions where the metal line is disconnected narrows a distance between the photoresist patterns, thereby causing the spacers to contact each other and preventing the micro metal patterns from being formed where the spacers contact each other.

A method of forming a metal line of a semiconductor device according to an aspect of the present invention includes forming a dielectric film on a semiconductor substrate. A plurality of parallel photoresist patterns are formed over the entire structure including the dielectric film. A spacer is formed on sidewalls of the photoresist patterns. The dielectric film is exposed by removing the photoresist patterns. Damascene patterns are formed by etching the exposed dielectric film. The spacer is removed. Metal material is formed over the entire structure including the damascene patterns. The metal material is then polished, thereby forming a metal line.

The photoresist patterns formed on a region where the metal line is disconnected extend outwardly in opposite directions at end portions thereof such that a space is defined between the end portions of the photoresist patterns.

A distance between the end portions is smaller than twice a width of the spacer.

A pitch of the photoresist patterns is twice as large as a pitch of the metal line.

After the dielectric film is formed, first and second hard mask films and an Anti-Reflective Coating (ARC) layer are formed over the dielectric film.

The first hard mask film and the second hard mask film are formed of a Spin On Coating (SOC) film and a Multi-Functional Hard Mask (MFHM) film, respectively. The MFHM may be a Si-containing BARC (Bottom ARC).

A method of forming a metal line of a semiconductor device according to another aspect of the present invention includes forming a dielectric film on a semiconductor substrate. A plurality of parallel photoresist patterns is formed over the entire structure including the dielectric film. The photoresist patterns adjacent to a region where the metal line is disconnected have portions projecting in a direction of the region where the metal line is disconnected. A spacer is formed on sidewalls of the photoresist patterns. The dielectric film is exposed by removing the photoresist patterns. Damascene patterns are formed by etching the exposed dielectric film. The spacer is removed. Metal material is formed over the entire structure including the damascene patterns. The metal material is then polished, thereby forming a metal line.

A distance between the projections of the photoresist patterns adjacent to the region where the metal line is disconnected is smaller than twice a width of the spacer.

A pitch of the photoresist patterns is twice as large as a pitch of the metal line.

After the dielectric film is formed, first and second hard mask films and an ARC layer are formed over the dielectric film.

The first hard mask film and the second hard mask film include a SOC film and a MFHM film, respectively.

### BRIEF DESCRIPTION OF THE DRAWINGS

FIGS. 1A to 5B are sectional views and plan views illustrating a method of forming a metal line of a semiconductor device according to an embodiment of the present invention; and

FIGS. 6A to 10B are sectional views and plan views illustrating a method of forming a metal line of a semiconductor device according to another embodiment of the present invention.

### DESCRIPTION OF SPECIFIC EMBODIMENTS

Specific embodiments according to the present invention will be described with reference to the accompanying drawings. The present invention is not limited to the disclosed embodiments, but may be implemented in various manners. The embodiments are provided to complete the disclosure of the present invention and to allow those having ordinary skill in the art to understand the present invention. The present invention is defined by the scope of the claims.

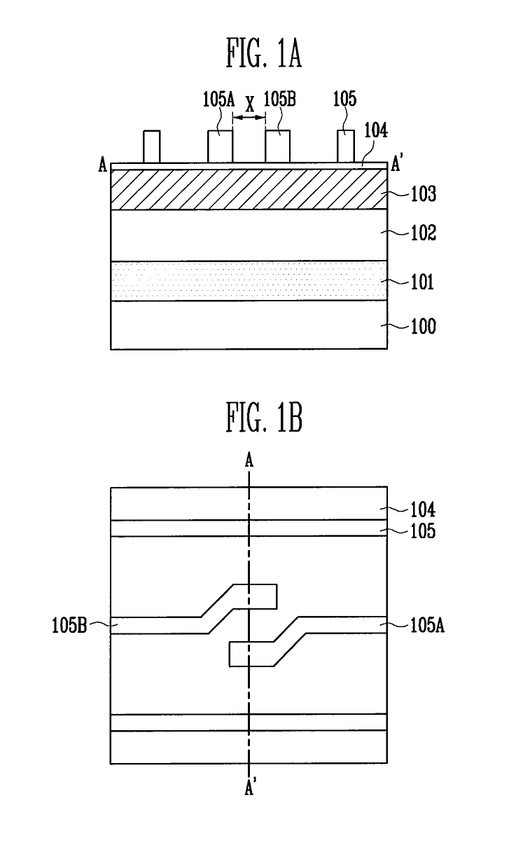

FIGS. 1A to 5B are sectional views and plan views illustrating a method of forming a metal line of a semiconductor device according to an embodiment of the present invention.

Referring to FIG. 1A, a dielectric film 101, a first hard mask film 102, a second hard mask film 103, and an ARC layer 104 are sequentially formed over a semiconductor substrate 100.

The dielectric film 101 can be formed of an oxide film. The first hard mask film 102 can be formed of a SOC film. The second hard mask film 103 can be formed of a MFHM film. The MFHM film contains Si and therefore generates a difference in the etch rate with the first hard mask film 102 formed of the SOC film in a subsequent etch process. Further, the MFHM film is transparent and can omit an additional key open process for pattern alignment when subsequent photoresist patterns are formed.

A photoresist film is coated over the entire structure including the ARC layer 104. Exposure and development processes are then performed, thereby forming photoresist patterns 105, 105A, and 105B. The pitch of the photoresist patterns 105 is approximately twice as large as that of a metal line to be formed ultimately.

In the formation process of the photoresist patterns, a distance X between the photoresist patterns 105A, 105B at portions where the metal line is disconnected may be smaller than twice the thickness of a spacer film to be formed subsequently.

Referring to FIG. 1B, the plurality of photoresist patterns 105, 105A, 105B are formed in parallel. However, the photoresist patterns 105A, 105B each extend diagonally outward toward one of the adjacent photoresist patterns 105 at the disconnected portions. An end portion of each of the photoresist patterns 105A, 105B then extends in parallel to the photoresist patterns 105 such that a space is formed between the end portions of the photoresist patterns 105A, 105B.

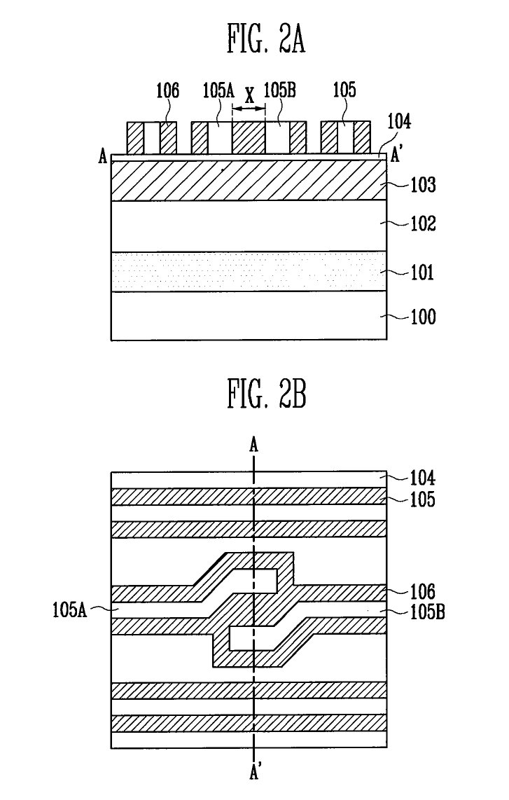

Referring to FIGS. 2A and 2B, a spacer 106 is formed on the sidewalls of the photoresist patterns 105, 105A, 105B. The space formed between the end portions of the photoresist patterns 105A, 105B is smaller than twice the thickness of the spacer 106. Thus, the spacer 106 fills the space between the photoresist patterns 105A, 105B at the disconnected portions of the metal line.

The spacer 106 can be formed by depositing an oxide film over the entire structure including the photoresist patterns 105, 105A, 105B and then performing an etch process such that the oxide film remains on the sidewalls of the photoresist patterns 105, 105A, 105B.

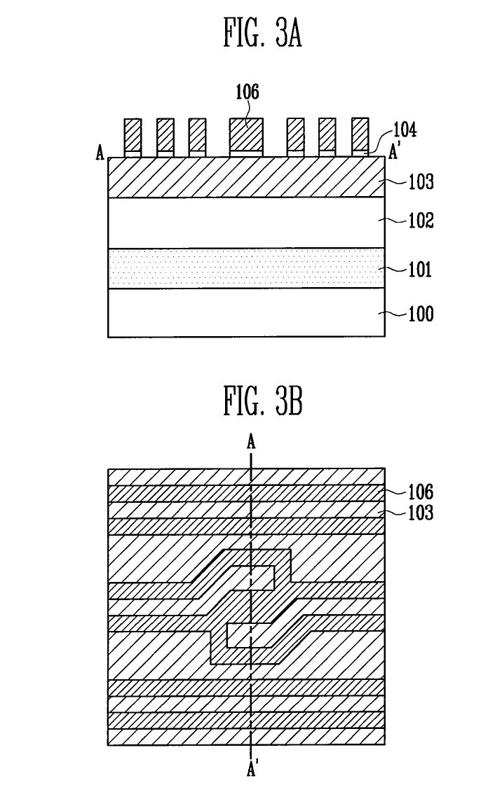

Referring to FIGS. 3A and 3B, the photoresist patterns are removed by performing a strip process. An exposed ARC layer is then removed. Etch patterns 104, 106 are formed in which the spacer 106 and the ARC layer 104 are laminated. The pitch of the etch patterns 104, 106 is approximately half the pitch of the photoresist patterns.

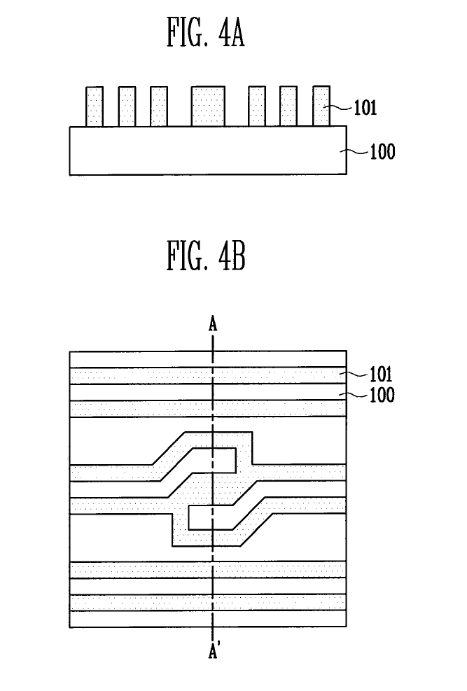

Referring to FIGS. 4A and 4B, the first and second hard mask films 102, 103 are sequentially etched by an etch process using the etch patterns as an etch mask, thereby forming hard mask patterns. Thereafter, the dielectric film 101 is patterned using an etch process employing the hard mask patterns to form damascene patterns for the metal line.

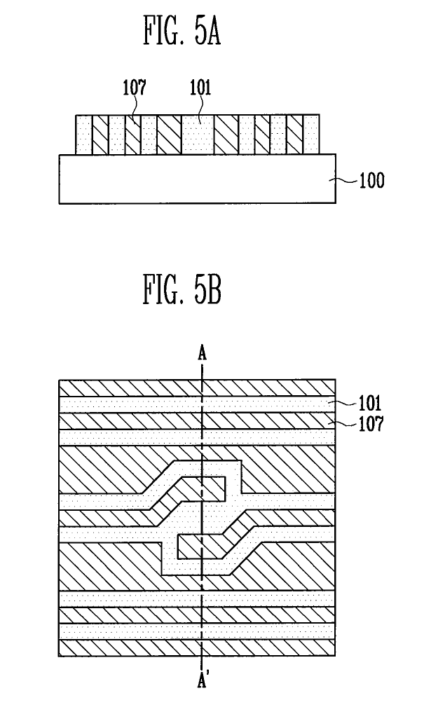

Referring to FIGS. 5A and 5B, metal material is formed over the entire structure including the dielectric film 101 in which the damascene patterns are formed. A polishing process is then performed so that the top surface of the dielectric film 101 is exposed. Thus, the metal material remains within the damascene patterns and, therefore, metal lines 107 are formed.

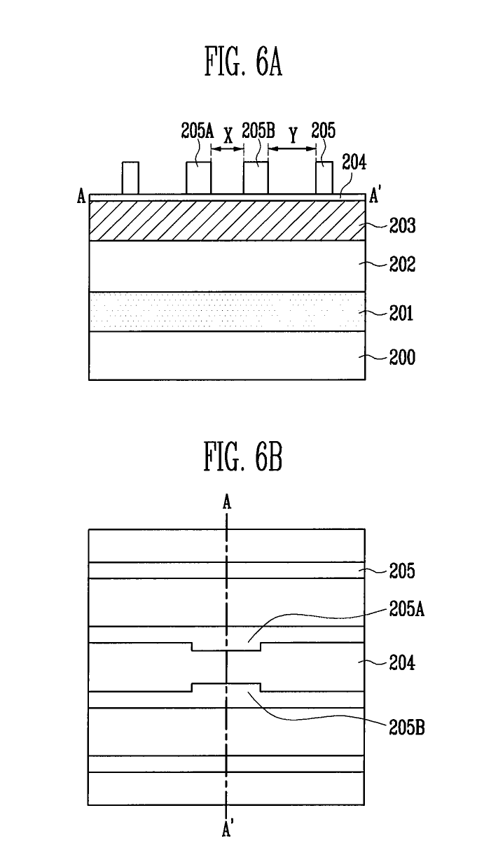

FIGS. 6A to 10B are sectional views and plan views illustrating a method of forming a metal line of a semiconductor device according to another embodiment of the present invention.

Referring to FIG. 6A, a dielectric film 201, a first hard mask film 202, a second hard mask film 203, and an ARC layer 204 are sequentially formed over a semiconductor substrate 200.

The dielectric film 201 can be formed of an oxide film. The first hard mask film 202 can be formed of a SOC film. The second hard mask film 203 can be formed of a MFHM film. The MFHM film contains Si and therefore generates a difference in the etch rate with the first hard mask film 202 formed of the SOC film in a subsequent etch process. Further, the MFHM film is transparent and can omit an additional key open process for pattern alignment when subsequent photoresist patterns are formed.

A photoresist film is coated over the entire structure including the ARC layer 204. Exposure and development processes are then performed, thereby forming photoresist patterns 205, 205A, and 205B. The pitch of the photoresist patterns 205 is approximately twice as large as that of a metal line to be formed ultimately.

In the formation process of the photoresist patterns, a distance X between the photoresist patterns 205A, 205B adjacent to portions where the metal line is disconnected may be smaller than twice the thickness of a spacer film to be formed subsequently.

Referring to FIG. 6B, the plurality of photoresist patterns 205, 205A, 205B are formed in parallel. The photoresist patterns 205A, 205B adjacent to the portions where the metal line is disconnected project inwardly toward each other.

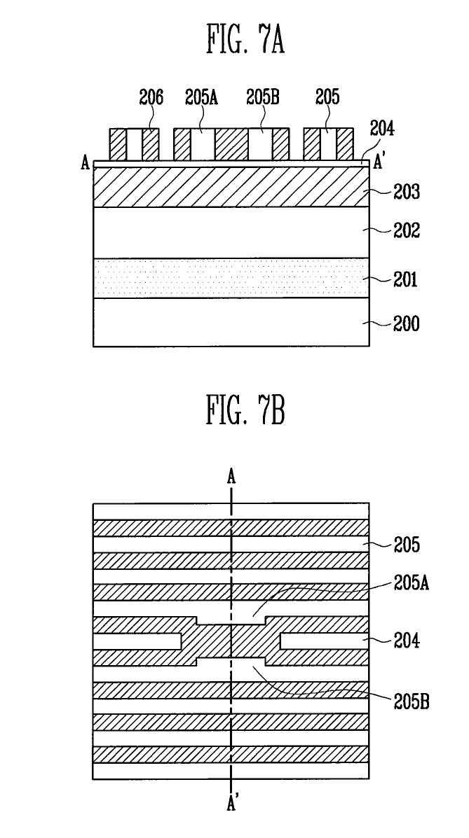

Referring to FIGS. 7A and 7B, a spacer 206 is formed on the sidewalls of the photoresist patterns 205, 205A, 205B. A space between projecting portions of the photoresist patterns 205A, 205B is smaller than twice the thickness of the spacer 206. Thus, the spacer 206 fills the space between the projecting portions of the photoresist patterns 205A, 205B.

The spacer 206 can be formed by depositing an oxide film over the entire structure including the photoresist patterns 205, 205A, 205B and then performing an etch process such that the oxide film remains on the sidewalls of the photoresist patterns 205, 205A, 205B.

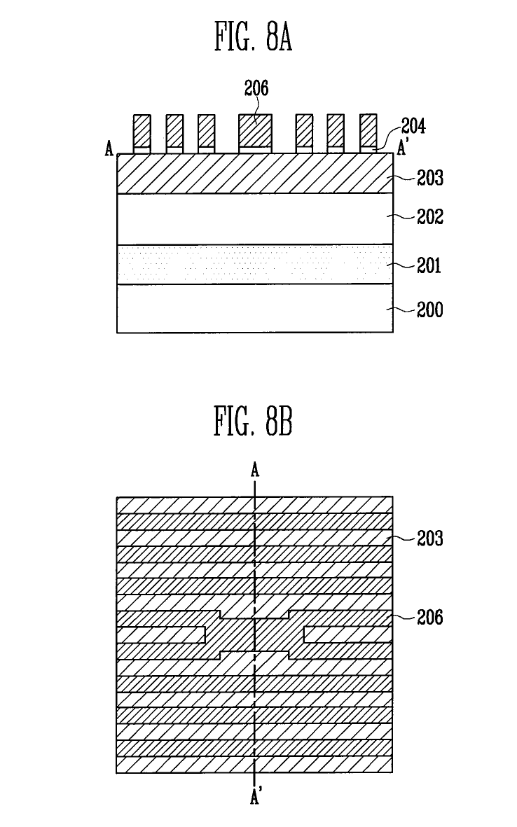

Referring to FIGS. 8A and 8B, the photoresist patterns 205, 205a, 205b are removed by performing a strip process. An exposed ARC layer is then removed. As a result, etch patterns 204, 206 are formed in which the spacer 206 and the ARC layer 204 are laminated. The pitch of the etch patterns 204, 206 is approximately half the pitch of the photoresist patterns.

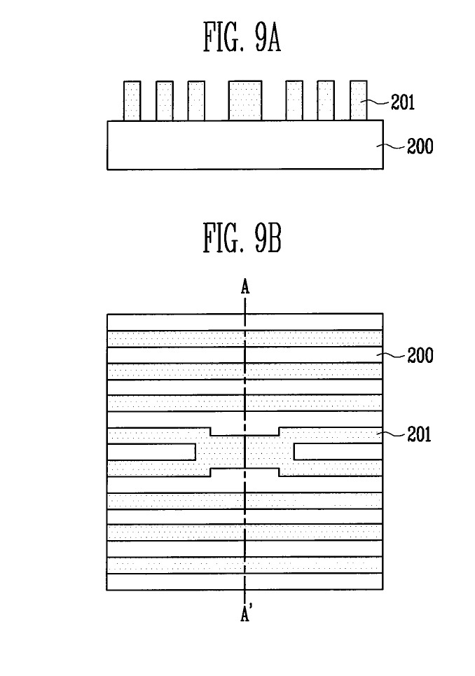

Referring to FIGS. 9A and 9B, the first and second hard mask films 202, 203 are sequentially etched by an etch process using the etch patterns as an etch mask, thereby forming hard mask patterns. Thereafter, the dielectric film 201 is patterned using an etch process employing the hard mask patterns to form damascene patterns for the metal line.

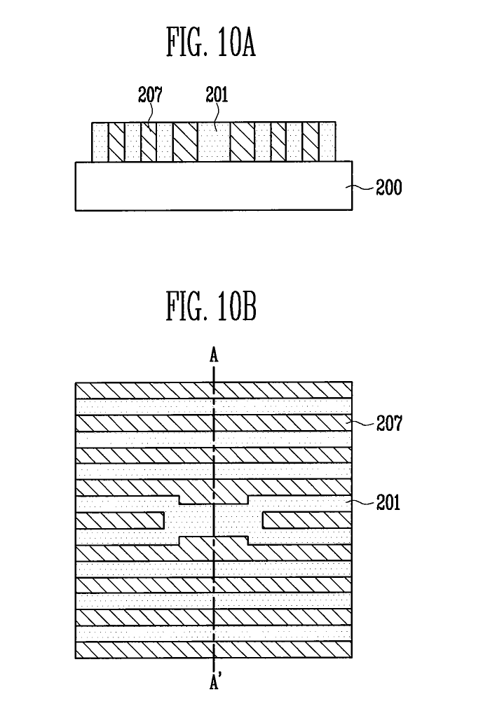

Referring to FIGS. 10A and 10B, metal material is formed over the entire structure including the dielectric film 201 in which the damascene patterns are formed. A polishing process is then performed so that the top surface of the dielectric film 201 is exposed. Thus, the metal material remains within the damascene patterns and, therefore, metal lines 207 are formed.

As described above, according to the present invention, the spacer film is formed on the sidewalls of the photoresist patterns, micro metal patterns are formed using the spacer as an etch mask, and portions where a metal line is disconnected narrows a distance between the photoresist patterns, thereby causing the spacers to contact each other and preventing the micro metal patterns from being formed between the narrowed portion between the photoresist patterns. Accordingly, a metal line having a line width smaller than the resolution of an exposure apparatus can be formed.

The embodiments disclosed herein have been proposed to allow a person skilled in the art to easily implement the present invention, and the person skilled in the art may implement the present invention by a combination of these embodiments. Therefore, the scope of the present invention is not limited by or to the embodiments as described above, and should be construed to be defined only by the appended claims and their equivalents.

What is claimed is:

1. A method of forming a metal line of a semiconductor device, the method comprising:
forming a dielectric film over a semiconductor substrate;
forming a plurality of parallel photoresist patterns over the dielectric film;
forming a spacer on sidewalls of the photoresist patterns;
removing the photoresist patterns to expose the dielectric film;
etching the exposed dielectric film to form damascene patterns;
removing the spacer;
forming metal material over the damascene patterns; and
polishing the metal material, thereby forming a metal line.

2. The method of claim 1, wherein the photoresist patterns formed on a region where the metal line is disconnected extend outwardly in opposite directions at end portions thereof such that a space is defined between the end portions of the photoresist patterns.

3. The method of claim 2, wherein a distance between the end portions of the photoresist patterns is smaller than twice a width of the spacer.

4. The method of claim 1, wherein a pitch of the photoresist patterns is approximately twice as large as a pitch of the metal line.

5. The method of claim 1, further comprising forming first and second hard mask films and an Anti-Reflective Coating (ARC) layer over the dielectric film, after the dielectric film is formed.

6. The method of claim 5, wherein the first hard mask film and the second hard mask film are formed of a Spin On Coating (SOC) film and a Multi-Functional Hard Mask (MFHM) film, respectively, the MFHM comprising Si-containing BARC (Bottom ARC).

7. A method of forming a metal line of a semiconductor device, the method comprising:
forming a plurality of parallel photoresist patterns over a dielectric film provided on a semiconductor substrate, wherein the photoresist patterns adjacent to a region where the metal line is disconnected have portions projecting in a direction of the region where the metal line is disconnected;
forming a spacer on sidewalls of the photoresist patterns;
removing the photoresist patterns to expose the dielectric film;
etching the exposed dielectric film to form damascene patterns;
removing the spacer;
forming metal material over the damascene patterns; and
polishing the metal material, thereby forming a metal line.

8. The method of claim 7, wherein a distance between the projecting potions of the photoresist patterns adjacent to the region where the metal line is disconnected is smaller than twice a width of the spacer.

9. The method of claim 7, wherein a pitch of the photoresist patterns is approximately twice as large as a pitch of the metal line.

10. The method of claim 7, further comprising forming first and second hard mask films and an ARC layer over the dielectric film, after the dielectric film is formed.

11. The method of claim 10, wherein the first hard mask film and the second hard mask film comprise a SOC film and a MFHM film, respectively.

12. A method of forming a metal line of a semiconductor device, the method comprising:
forming a plurality of parallel photoresist patterns over a dielectric film provided on a semiconductor substrate, wherein the photoresist patterns formed on a region where the metal line is disconnected are configured to define a space therebetween, a distance of the space being smaller than twice a width of the spacer;
forming a spacer on sidewalls of the photoresist patterns;
removing the photoresist patterns to expose the dielectric film;
etching the exposed dielectric film to form damascene patterns;
removing the spacer;
forming metal material over the damascene patterns; and
polishing the metal material, thereby forming a metal line.

13. The method of claim 12, wherein the photoresist patterns formed on the region where the metal line is disconnected extend outwardly in opposite directions at end portions thereof such that the space is defined between the end portions of the photoresist patterns.

14. The method of claim 12, wherein the photoresist patterns formed on the region where the metal line is disconnected have portions projecting in a direction of the region where the metal line is disconnected such that the space is defined between the projecting portions.
